(19) United States
(12) Patent Application Publication
(10) Pub. No.: US 2024/0319250 A1
(43) Pub. Date: Sep. 26, 2024

(54) MULTI-FUNCTIONAL, HIGH-DENSITY ELECTRICAL-GRID MONITORING

(71) Applicants: 3M Innovative Properties Company, St. Paul, MN (US); Connected Intelligence Systems Ltd., Netanya (IL)

(72) Inventors: Douglas B. Gundel, Cedar Park, TX (US); Johannes Fink, Bergheim (DE); David V. Mahoney, Austin, TX (US); Eyal Doron, Caesarea (IL); Uri Bar-Ziv, Zichron Yaakov (IL)

(21) Appl. No.: 18/574,242

(22) PCT Filed: Jun. 13, 2022
(86) PCT No.: PCT/US22/72901

§ 371 Date: Dec. 26, 2023

Related U.S. Application Data
(60) Provisional application No. 63/202,861, filed on Jun. 28, 2021.

(51) Int. Cl. G01R 31/08; H02J 13/00; H04B 3/54

(52) U.S. Cl. CPC G01R 31/085; H02J 13/00002; H02J 13/00007; H04B 3/54

(57) ABSTRACT

In general, a system configured to monitor one or more conditions of an electric powerline having one or more electrical cables includes at least one primary node operatively coupled to at least one electrical cable of the one or more electrical cables and communicatively coupled to a central computing system; and at least one secondary node operatively coupled to at least one electrical cable of the one or more electrical cables and configured to communicate data via powerline communication to the at least one primary′ node, wherein the at least one primary node is configured to deliver the data to the central computing system.

This application claims priority to U.S. Provisional Application No. 63/202,861, filed Jun. 28, 2021, which is incorporated herein by reference in its entirety.

### TECHNICAL FIELD

The present disclosure relates to the field of electrical equipment, including power cables and accessories, for power utilities and industrial and commercial sites.

### BACKGROUND

Electrical power grids include numerous components that operate in diverse locations and conditions, such as above ground, underground, cold weather climates, and/or hot weather climates. When a power grid suffers a failure, it can be difficult to determine the cause of the failure. Sensor systems for power networks, especially underground power networks, are increasingly becoming employed to detect grid anomalies (such as faults or precursors of faults) so that an operator can react more quickly, effectively, and safely to maintain service or return the system to service. Examples of sensor systems include faulted-circuit indicators, reverse-flow monitors, and power-quality monitors. Commonly assigned U.S. Pat. No. 9,961,418, incorporated by reference herein in its entirety, describes an underground power-network-monitoring system that communicates with a central system. Commonly assigned International Patent Application No. PCT/US2020/067683, incorporated by reference herein in its entirety, describes techniques for capacitively coupling monitoring devices to an electrical power network.

### SUMMARY

In general, the present disclosure provides systems and techniques for monitoring an electric power grid, e.g., for evaluating a condition of power cables and/or other electrical equipment. The systems described herein include a distributed hierarchy of monitoring devices, or “nodes.” For instance, a monitoring system may include one or more “primary” nodes configured to communicate directly with a central monitoring system, as well as one or more “secondary” nodes configured to communicate, via powerline-communication techniques, with primary nodes and/or with other secondary nodes. Distributing the monitoring devices in this way enables a substantially dense node-coverage of a power grid, e.g., enabling precise determinations of the locations of electrical faults or other anomalies, while simultaneously reducing both a cost and complexity that would otherwise be associated with a similar density of coverage composed only of primary nodes all directly communicating to the central monitoring system.

In some examples herein, a system configured to monitor one or more conditions of an electric powerline having one or more electrical cables includes at least one primary node operatively coupled to at least one electrical cable of the one or more electrical cables and communicatively coupled to a central computing system; and at least one secondary node operatively coupled to at least one electrical cable of the one or more electrical cables and configured to communicate data via powerline communication to the at least one primary node, wherein the at least one primary node is configured to deliver the data to the central computing system. In some examples, the primary and secondary nodes are configured to retrofit to an existing electrical powerline.

The details of one or more examples of the disclosure are set forth in the accompanying drawings and the description below. Other features, objects, and advantages of the disclosure will be apparent from the description and drawings, and from the claims.

### BRIEF DESCRIPTION OF THE DRAWINGS

FIGS. 1A and 1B are conceptual diagrams illustrating respective example power-cable constructions.

FIG. 2A is a conceptual block diagram of an example electrical power network including primary and secondary monitoring nodes.

FIG. 2B is a conceptual block diagram of an example electrical power grid with primary and secondary monitoring nodes positioned at electrical cables and accessories.

FIG. 3A is a conceptual block diagram of an example electrical-network-monitoring system in which secondary monitoring nodes communicate, via powerline communication, only with primary nodes.

FIG. 3B is a conceptual block diagram of another example electrical-network-monitoring system in which secondary monitoring nodes communicate either with primary nodes and/or with other secondary nodes configured to rebroadcast the received signals.

FIG. 4 is a schematic view of one example configuration for a primary monitoring node, including a pad-mounted data communication system.

FIGS. 5 and 6 are schematic diagrams of example techniques for coupling primary and/or secondary monitoring nodes to power cables, enabling powerline communication.

FIG. 7A is a block diagram illustrating an example configuration for a secondary monitoring node electrically coupled to a power-delivery system via a removable T-body connector.

FIG. 7B is a block diagram illustrating an example configuration for a secondary monitoring node electrically coupled to a power-delivery system via a removable elbow connector.

FIG. 7C is a block diagram illustrating an example configuration for a secondary monitoring node, in which the coupling mechanism and the electronics are located in a plug with external connections optionally routed through an end cap. Removal of the end cap exposes a test point to enable local determination of whether the powerline is currently energized.

FIG. 7D is a block diagram illustrating an example configuration for a secondary monitoring node, in which the node coupling is located in the plug and the electronics are housed in an extension module that is removably or permanently connected to the plug. Connection to other devices and sensors can optionally be routed through the end cap.

FIG. 7E is a block diagram illustrating an example configuration for a secondary monitoring node, in which the primary node coupling is located in the plug and the electronics are housed in the end cap with external connections.

FIG. 7F is a block diagram illustrating an example configuration for a secondary monitoring node, in which the coupling is located in the plug, the connections are housed in the end cap, and the electronics are housed in a physically distinct module.

FIG. 8A is a diagram illustrating an example of a secondary monitoring node coupled to a single phase of an electrical cable.

FIG. 8B is a diagram illustrating an example arrangement in which multiple secondary nodes are connected locally on a multiphase electrical cable. Data can be shared between the phases for timing or for communication redundancy. If more than one phase is coupled to the same electronics, the communication can be sent on two or more lines for redundancy, e.g., if a channel is disrupted, or the signal can be distributed on two or more lines.

FIG. 8C is a diagram illustrating another example polyphase deployment of secondary nodes in which processing circuitry for multiple secondary nodes may be located within just one of the secondary nodes, with a data connection or other direct coupling between each of the secondary nodes.

FIG. 8D is a diagram illustrating another polyphase deployment of secondary nodes in which processing circuitry for multiple secondary nodes is housed within a distinct module communicatively coupled to each phase of the cable.

FIG. 9 is a flowchart illustrating example techniques for monitoring an electric power network, in accordance with this disclosure.

It is to be understood that the embodiments may be utilized, and structural changes may be made without departing from the scope of the invention. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Examples of the present disclosure include devices, techniques, and systems for sensing, communicating, and characterizing a condition of an electrical grid. As such, the example devices described herein include multifunctional (sensing, communication, and characterization) devices. In this aspect, example devices may include a coupling layer that can provide a sensing layer that senses native signals and intentional (e.g., injected) signals. Moreover, the coupling layer may also provide for communication (e.g., signal injection, signal reception) and channel characterization.

Some example techniques herein include coupling a sensing-and-communicating (“monitoring”) system onto a medium-voltage (MV) or high-voltage (HV) electrical-power-cable system. In particular, the monitoring systems described herein include a distributed hierarchy of monitoring devices, or “nodes.” For instance, a monitoring system may include at least one “primary” monitoring node and at least one “secondary” monitoring node. In general, the secondary nodes described herein may be less technically complex than the primary nodes. This lower complexity, and accordingly, lower per-unit cost, facilitates a higher density of coverage of the power-cable system with a network of monitoring nodes. For instance, the primary nodes may include more complex processing and/or communication capabilities, e.g., configured to communicate monitoring data directly to a central computing system. By contrast, the secondary nodes may include more-limited data-processing functionality, and may be configured to communicate only to other monitoring nodes within the monitoring system. In some examples, the secondary monitoring nodes are further configured to communicate only via the powerline-communication techniques detailed herein.

In some examples, a monitoring system may be retrofitted onto an existing MV or HV cable system, rather than incorporating a monitoring system within a cable system at the time of manufacture of the cable system. In some such retrofit examples, the techniques of this disclosure include coupling the systems without compromising the integrity of the cables, e.g., by cutting the cables or penetrating a radial layer of the cables (e.g., a cable jacket). For instance, some example techniques herein include capacitively coupling a partial-discharge (PD) detection system to a cable shield of a power cable. Additional and/or alternative example techniques herein include specialized removable connector devices to removably couple the secondary monitoring nodes to the power network.

The example devices and coupling techniques described herein enable the devices to communicate information, such as PD information, faulted-circuit indicator (FCI) information, electrical-current information, temperature information, or other information pertinent to the monitoring and maintenance of the electrical power network. Each coupling layer can be connected to a signal wire that can convey the detected or injected signal to or from a source, detector, processor, or other device. In some embodiments, a protective cover or wrapping can also be utilized to cover or protect the coupling layer and/or signal wire connection.

In accordance with aspects of this disclosure, for distributed networks on an electrical-power grid, example devices are configured to interface with an electrical-power cable with little-to-no modification or other alteration of the power cable, thereby reducing the potential for cable damage. Example systems herein are configured to use these example devices and coupling techniques to communicate along the powerline via a powerline-communication technique. In some examples, the devices may be retrofittable to an existing powerline. Alternatively, the techniques herein may be applied to example devices that are coupled to (e.g., integrated) with a newly installed powerline.

The multifunctional devices described herein can be integrated with various critical monitoring functionalities to support a grid operator in maintaining grid service or returning the grid to service when grid service is unavailable. For example, an FCI can include electrical-current sensing, hardware for processing FCI information, fault logic, communication, and power (e.g., potentially through inductive power-harvesting from the powerline). These systems and devices can be readily packaged in a (secondary) retrofittable node that has communication only along the powerline (e.g., communication only to other nodes in the network). Other supported functionalities can include power-quality monitoring, PD monitoring, discrete-temperature monitoring, fault location, time-domain or frequency-domain reflectometry, incipient fault detection, and other functions. In some examples, these other functions also can be supported by a retrofittable coupling mechanism to reduce the cost per device and complexity of deployment. For enabling communication, in accordance with techniques of this disclosure, the retrofittable coupling system can support communication to a primary, centrally connected node from a secondary, satellite node, or from the satellite node to another secondary node.

Powerlines may transmit electrical power from a power source (e.g., a power plant) to a power consumer, such as a business or home. Powerlines may be underground, underwater, or suspended overhead (e.g., from wooden poles, metal structures, etc.). Powerlines may be used for electrical-power transmission at relatively high voltages (e.g., compared to electrical cables utilized within a home, which may transmit electrical power between approximately 12 volts and approximately 240 volts depending on application and geographic region). For example, powerlines may transmit electrical power above approximately 600 volts (e.g., between approximately 600 volts and approximately 1,000 volts). However, it should be understood that powerlines may transmit electrical power over any voltage and/or frequency range. For example, powerlines may transmit electrical power within different voltage ranges. In some examples, a first type of powerline may transmit voltages of more than approximately 1,000 volts, such as for distributing power between a residential or small commercial customer and a power source (e.g., power utility). As another example, a second type of powerline may transmit voltages between approximately 1 kV and approximately 69 kV, such as for distributing power to urban and rural communities. A third type of powerline may transmit voltages greater than approximately 69 kV, such as for sub-transmission and transmission of bulk quantities of electric power and connection to very large consumers.

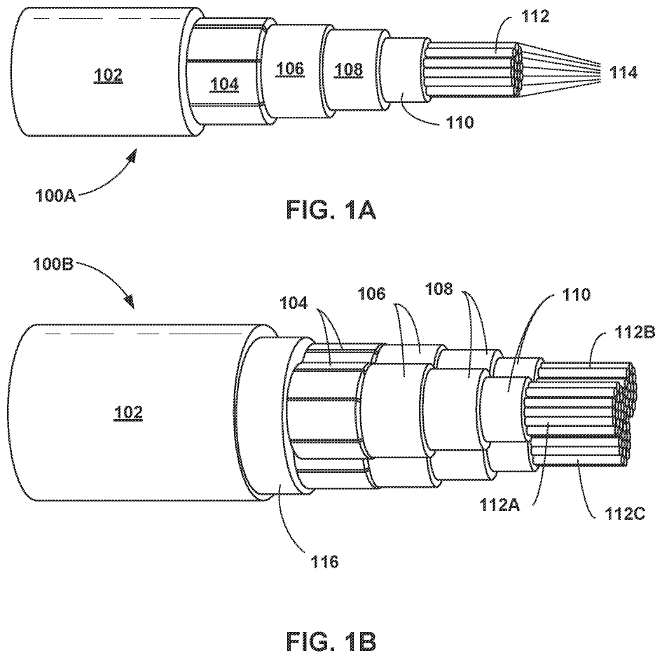

Powerlines include electrical cables and one or more electrical cable accessories. For example, FIGS. 1A and 1B depict two example electrical-power cables 100A and 100B (collectively, “cables 100,” or, in the alternative, “cable 100”), respectively. Power cable 100A is an example of a “single phase” MV cable, e.g., having only a single central conductor 112. Power cable 100A includes jacket or oversheath 102, metal sheath or cable shield 104, insulation screen 106, insulation 108, conductor screen 110, and central conductor 112. Power cable 100B is an example of a three-phase extruded medium-voltage (MV) cable, e.g., having three central conductors 112A-112C (collectively, “conductors 112,” or, in the alternative, “conductor 112”). Polyphase cables like cable 100B can carry more than one shielded-conductor 112 within a single jacket 102. Other examples of typical, but not depicted, cable layers include swellable or water-blocking materials that are placed within the conductor strands 114 (“strand fill”), or between various other layers of the cable 100 (“filler 116”).

Example cable accessories may include splices, separable connectors, terminations, and connectors, among others. In some examples, cable accessories may include cable splices configured to physically and conductively couple two or more cables 100. For example, a cable accessory can physically and conductively couple cable 100A or cable 100B to other electrical cables. In some examples, terminations may be configured to physically and conductively couple a cable 100 to additional electrical equipment, such as a transformer, switch gear, power substation, business, home, or other structure.

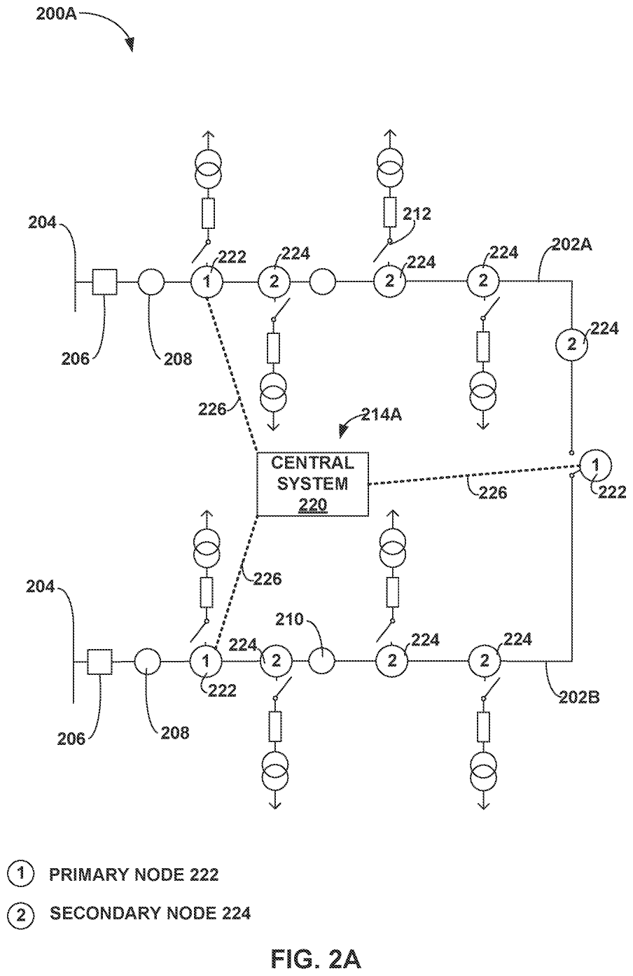

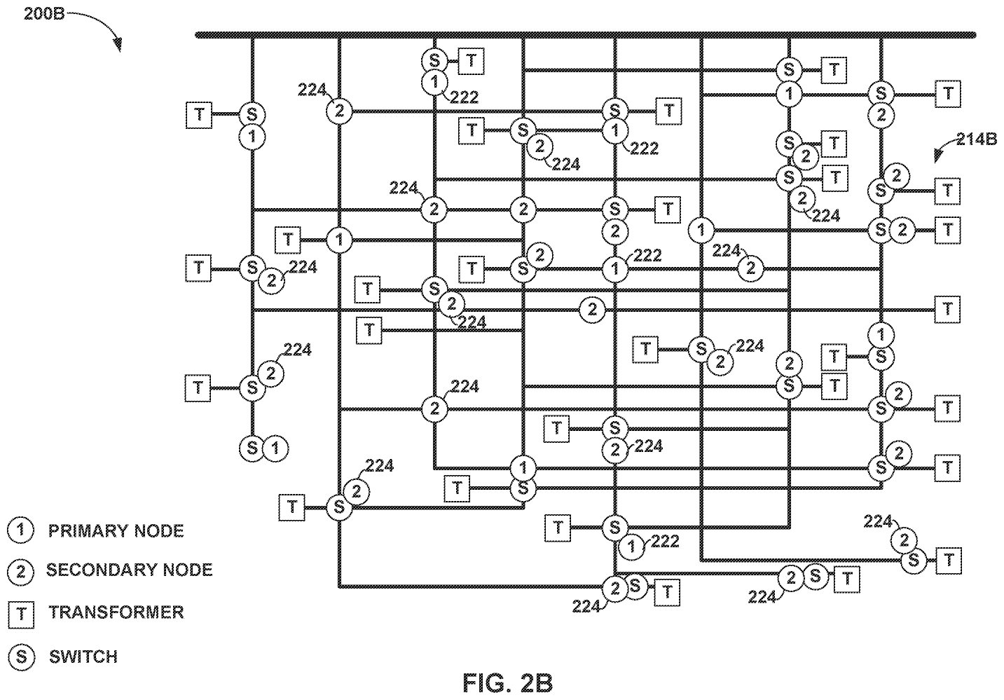

Electrical cables 100 and cable accessories can be assembled into an electrical power network, or in some specific examples thereof, an electrical power grid, to distribute electrical power to various consumers or other end-users. For instance, FIG. 2A is a conceptual block diagram depicting a first example electrical power network 200A. For instance, power network 200A includes at least two power-transmission lines or “feeder” lines 202A, 202B (collectively, “feeder lines 202”), which may be examples of power cables 100 of FIGS. 1A and 1B. Distributed along feeder lines 202, power network 200A includes one or more substation buses 204, circuit breakers 206, automatic circuit reclosers (ACRs) 208, sectionalizers 210, electrical switches 212 (e.g., with voltage transformers), and/or other cable accessories.

In accordance with techniques of this disclosure, power network 200A includes a monitoring system 214A configured to collect and process data indicative of one or more conditions of the power network. As described herein, monitoring system 214 includes a central computing system 220, at least one “primary” monitoring node 222 operatively coupled to feeder lines 202, and at least one “secondary” monitoring node 224 operatively coupled to feeder lines 202 at some distance away from the primary monitoring node 222. For instance, the secondary monitoring node 224 may be positioned greater than about 5 meters away from primary monitoring node 222, such as greater than 10 meters away, or greater than 25 meters away.

As detailed further below, primary monitoring devices 222 and secondary monitoring devices 224 may include one or more sensors, one or more communication devices, and/or one or more power-harvesting devices, which may be operatively coupled to insulation screen 106 (FIG. 1) of the cable 202 to perform a variety of functions. The one or more sensors can output sensor data indicative of conditions of the cable 202 or a proximate cable accessory. Examples of such sensors include temperature sensors, partial-discharge (PD) sensors, smoke sensors, gas sensors, and acoustic sensors, among others.

According to further aspects of this disclosure, computing system 220, such as a remote computing system and/or a computing device integrated with one or more of primary monitoring devices 222, determines a “health” of the cable and/or cable accessory based at least in part on the coupling and/or other sensor data. For example, computing system 220 may, e.g., in real-time, determine whether a cable accessory will fail within a predetermined amount of time based at least in part on the sensor data. By determining a health of the cable accessories and predicting failure events before they occur, computing system 220 may more-quickly and more-accurately identify potential failure events that may affect the distribution of power throughout the power grid, or worker and/or civilian safety, to name only a few examples. Further, central computing system 220 may proactively and preemptively generate notifications and/or alter the operation of power network 200A before a failure event occurs.

As indicated by dashed lines 226 in FIG. 2A, each primary monitoring node 222 includes a direct data connection with central computing system 220. For instance, each primary node 222 may communicate data with central computing system 220 via any or all of a wireless data communication, a mesh network, an Ethernet network, fiber optic cables, or a direct electrical integration (e.g., common electrical circuitry) with central computing system 220. By comparison, secondary nodes 224 do not include such capabilities to establish a direct data connection with central computing system 220, and instead, communicate data along the powerline 202 to which the secondary nodes 224 are coupled. The data will be received, through the powerline 202, either by another secondary node 224, which may then re-broadcast the data further along the powerline 202, or instead, by a proximate primary node 222. In response to receiving data from a secondary node 224, a primary node 222 may either transmit the received data directly to the central computing system 220, or instead, may first perform certain low-level data-processing (e.g., local analytics) prior to transmission to central computing system 220.

FIG. 2B is a conceptual block diagram illustrating another example electrical power network 200B that includes a distributed, hierarchical network of monitoring nodes. More specifically, power network 200B of FIG. 2B represents a “mesh” power grid, e.g., electrically coupled to a power source (not shown) and configured to supply electrical power to a geographic region (or any subdivision thereof, including a city, a city block, or even an individual building).

In the example illustrated in FIG. 2B, electrical power network 200B (also referred to herein as “power grid 200B”) is fitted with a monitoring system 214B that includes a plurality of primary nodes 222 and a plurality of secondary nodes 224. Additionally, power grid 200B includes a plurality of transformers (labeled “T” in FIG. 2B) and electrical switches (labeled “S” in FIG. 2B). As illustrated in FIG. 2B, power grid 200B includes a relatively dense coverage of monitoring nodes 222, 224, particularly at or near cable accessories or other devices, along relatively continuous stretches of the cables 202 themselves, and at cable branches or cable intersections. The dense coverage of the grid enables highly precise sensor measurements and grid monitoring, e.g., any measurements made or detected by sensors of a monitoring node can only be associated with a relatively small region of the grid, providing for rapid and precise localization should any anomalies arise. Additionally, because the grid coverage is augmented by secondary monitoring nodes 224, having a more-basic internal architecture than the primary nodes 222, this dense grid coverage may be enabled without substantially increasing the cost of the grid-monitoring system 214B.

As described herein, grid-monitoring systems 214A, 214B, via sensors coupled to and/or incorporated within primary nodes 222 and secondary nodes 224, are configured to collect data that indicates one or more of a health of a component of an electric powerline; one or more environmental conditions at the respective primary node 222 or secondary node 224; a state or operability of electrical grid 200B comprising the electric powerline; a presence of a fault in the electric powerline; or a location of a fault in the electric powerline.

More specifically, in accordance with techniques of this disclosure, secondary monitoring nodes 224 are configured to sense and/or transmit via powerline communication to another monitoring node, data that indicates one or more of a fault direction; fault measurements; fault alerts; electrical-asset-health alerts; a partial-discharge magnitude; a partial-discharge waveform; a partial-discharge calibration: partial-discharge statistical information; partial-discharge-based alerts; incipient faults; a temperature; cable diagnostic signals; a current waveform or a voltage waveform; waveform-based alerts; relative current phase information and relative voltage phase information; a current magnitude and current phase; a voltage magnitude and voltage phase; an impedance; power-quality measurements; load measurements; an amount of reactive power or active power; an estimated distance between the at least one secondary node and a detected fault, a detected partial-discharge event, or a waveform anomaly; relative time references or absolute time references: an identifier for the at least one secondary node; actuation and control signals: or timing or synchronization signals.

In some examples, but not all examples, in addition to monitoring conditions of grid 200B, monitoring system 214B is further configured to control field devices associated with power grid 200B. For instance, monitoring system 214B, via local primary or secondary monitoring nodes, may be configured to locally monitor and control the configurations (e.g., tap positions) of one or more of electrical switches, transformers, capacitor banks, or the like.

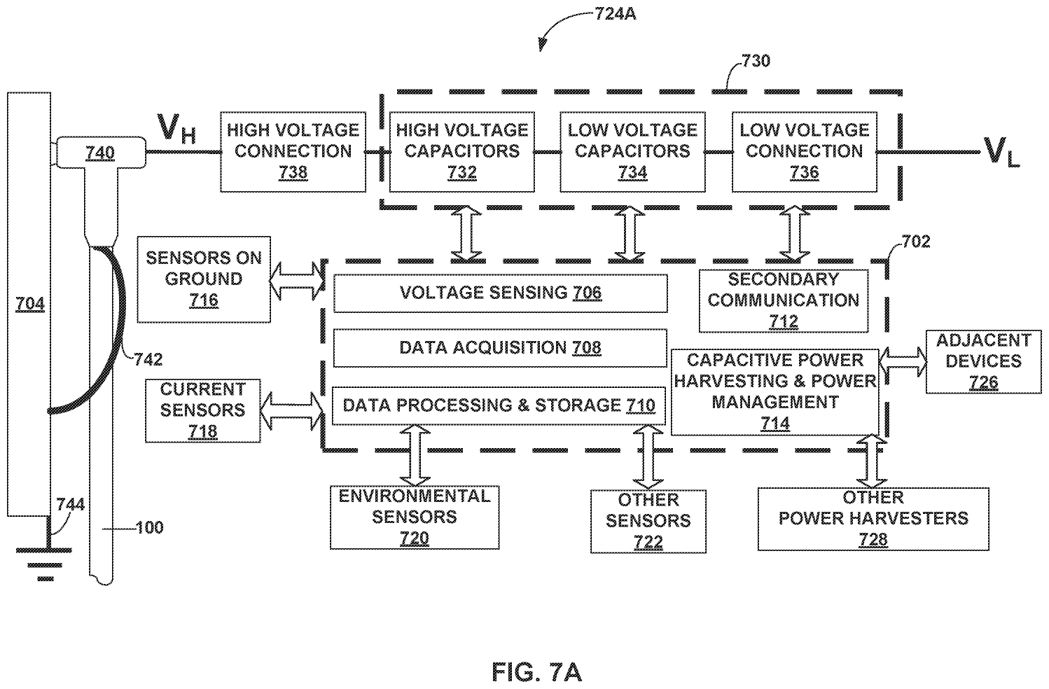

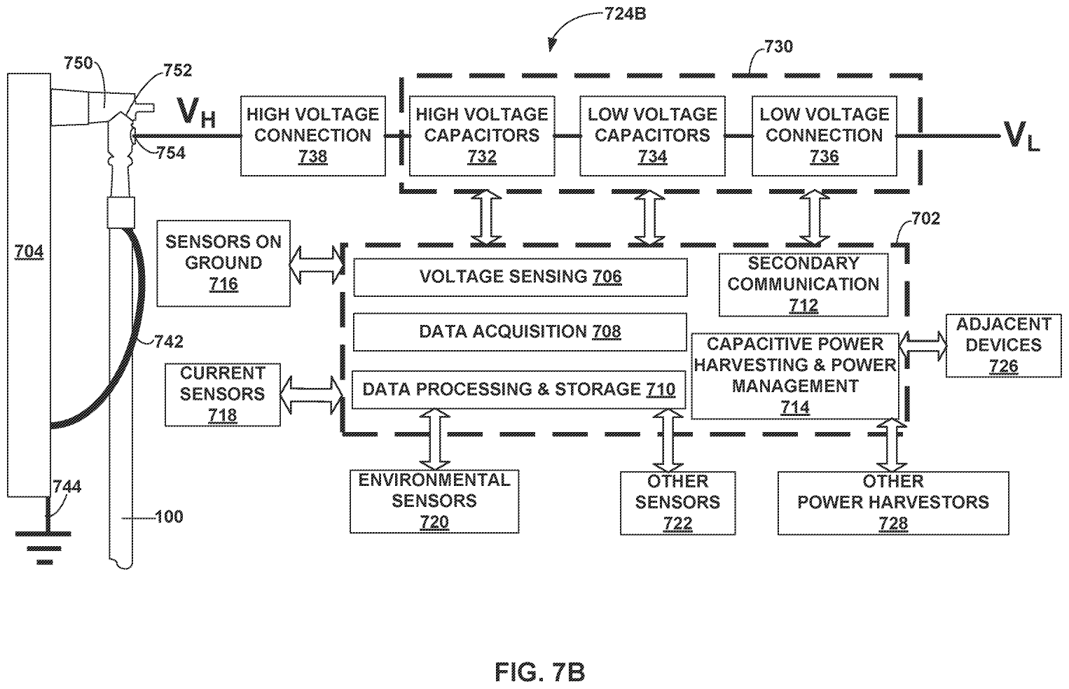

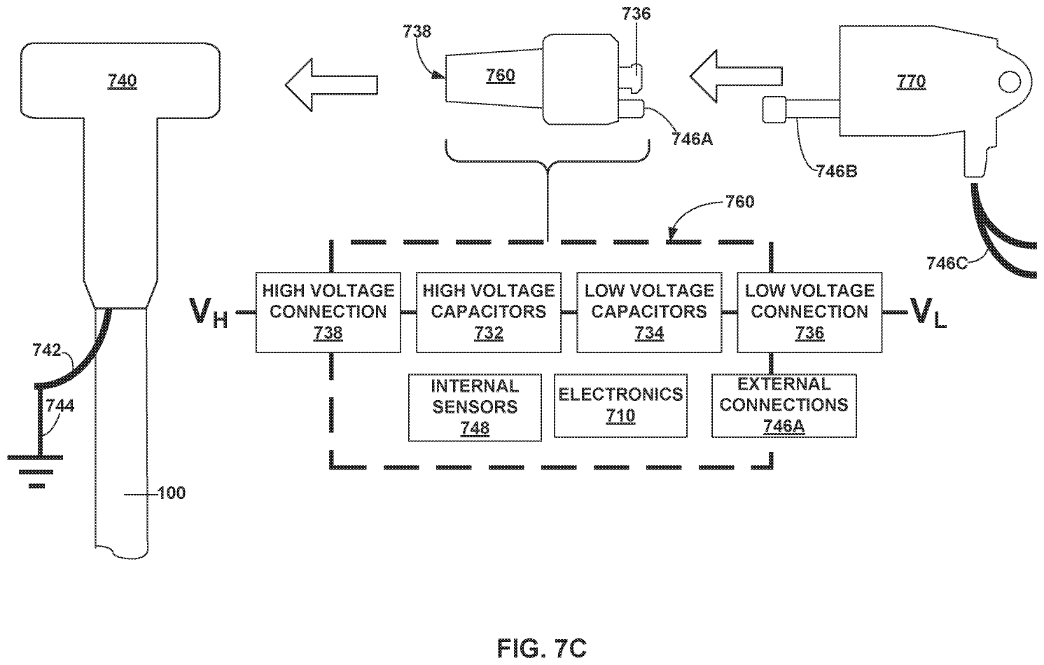

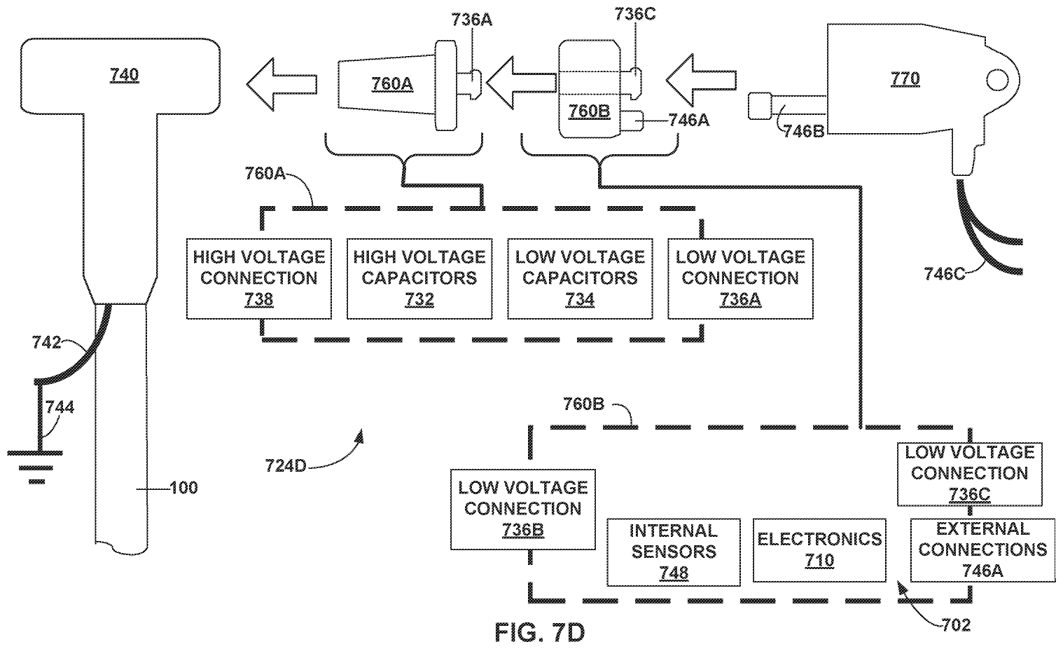

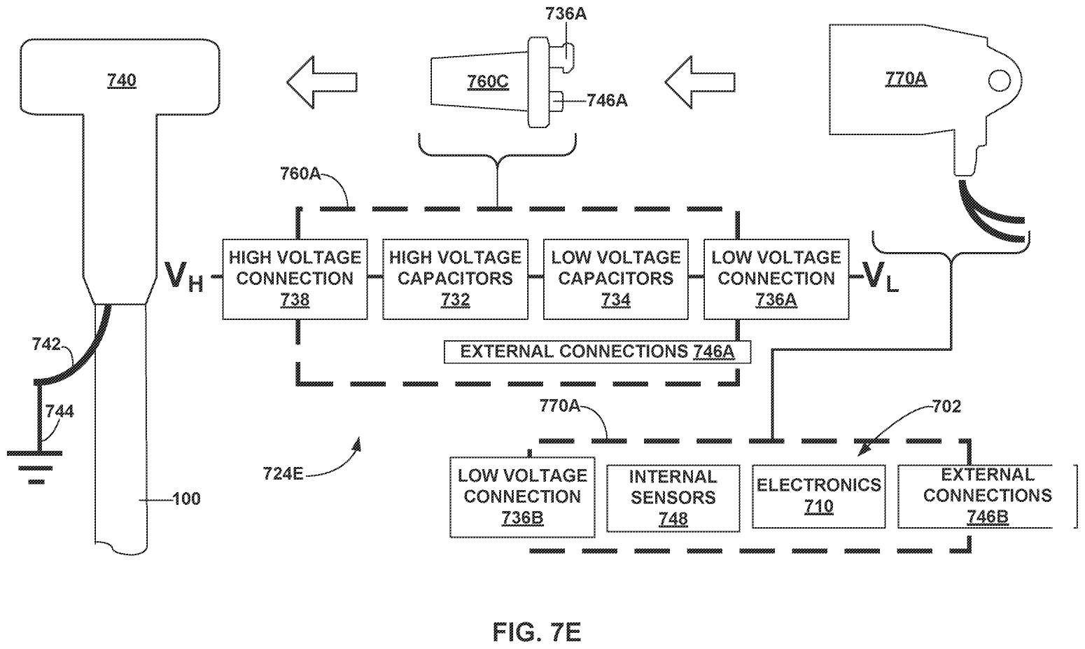

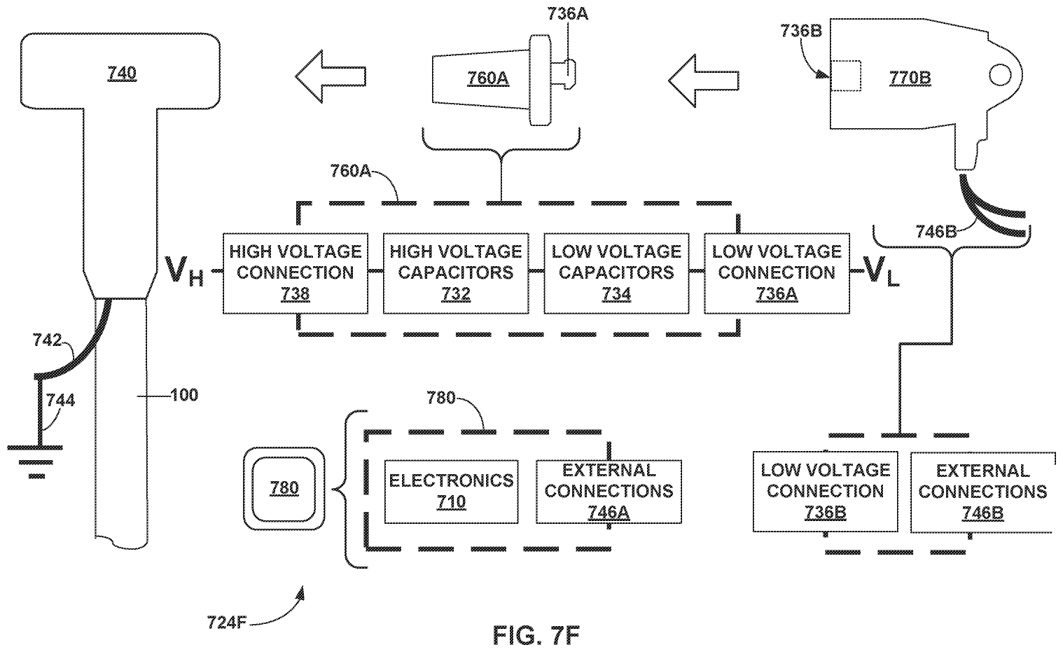

As described herein, one or more techniques of this disclosure include effectively converting or “upgrading” an electrical power network (e.g., grid 200B) into both a power network and a data-communication network. For instance, as detailed further below with respect to FIGS. 7A-7F, monitoring system 214B (and in particular, secondary monitoring nodes 224, referred to collectively as a “secondary network”) is configured to operatively couple to one or more electronic devices, in order to provide both electrical power and data-communication capabilities for the electronic device(s). Examples of such electronic devices may be virtually limitless, including sensors, cameras, or computing device(s), e.g., having intended functionality that may or may not be associated with monitoring conditions of power network 200B.

For example, as shown and described below with respect to FIGS. 7A-7F, secondary monitoring nodes 224 (and/or distinct connector devices 740, 750) include integrated data-communication interfaces, such as fiber-optic data interfaces, wired data interfaces, wireless data interfaces (e.g., for device-to-device data communication), or powerline communication (“PLC”) couplings (e.g., for connecting directly to the secondary network). Data communicated via these interfaces may or may not be associated with monitoring conditions of (or controlling) power network 200B. Additionally or alternatively, electronic devices may be coupled to a different electrical component (e.g., a cable accessory coupled to the powerline), e.g., that is located “upstream” or “downstream” from a monitoring node of system 214B. Once appropriately connected, the electronic device(s) may then communicate data via the powerline, for instance, via the powerline-communication techniques enabled by the respective monitoring node(s).

For instance, in a first illustrative example, a (human) user may submit user input via a user interface (e.g., keyboard, touchpad, display) of an electronic device that is operatively coupled to monitoring system 214B as described above. Monitoring system 214B then communicates the user input to a remote device (e.g., central system 220 or another monitoring node) via the data-communication techniques described herein.

In a second illustrative example, nodes 222, 224 of monitoring system 214B may be configured to “actively” handle information-access requests (e.g., web pages or other web client-server requests) between two or more locations. In a third illustrative example, a server or computer can “passively” send information along the network of monitoring nodes to another (e.g., remote) computing device, with minimal or no active processing by any of the monitoring nodes involved.

In a fourth illustrative example, an “independent” data network (e.g., an integrated security system or climate-control system for a building) may either partially interface, or fully integrate, with powerline monitoring system 214B such that monitoring nodes 222, 224 can provide some or all of the data-processing functionality of the independent data network. Such techniques may reduce the number of distinct devices needed to operate the independent data network and/or eliminate the need for an indirect connection to a power source.

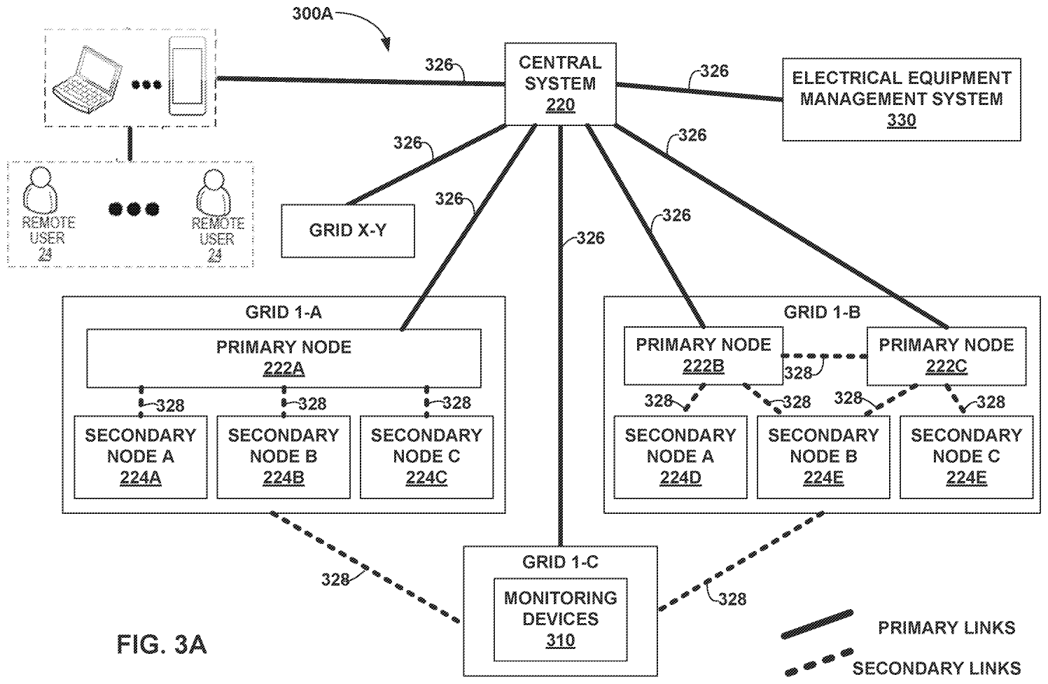

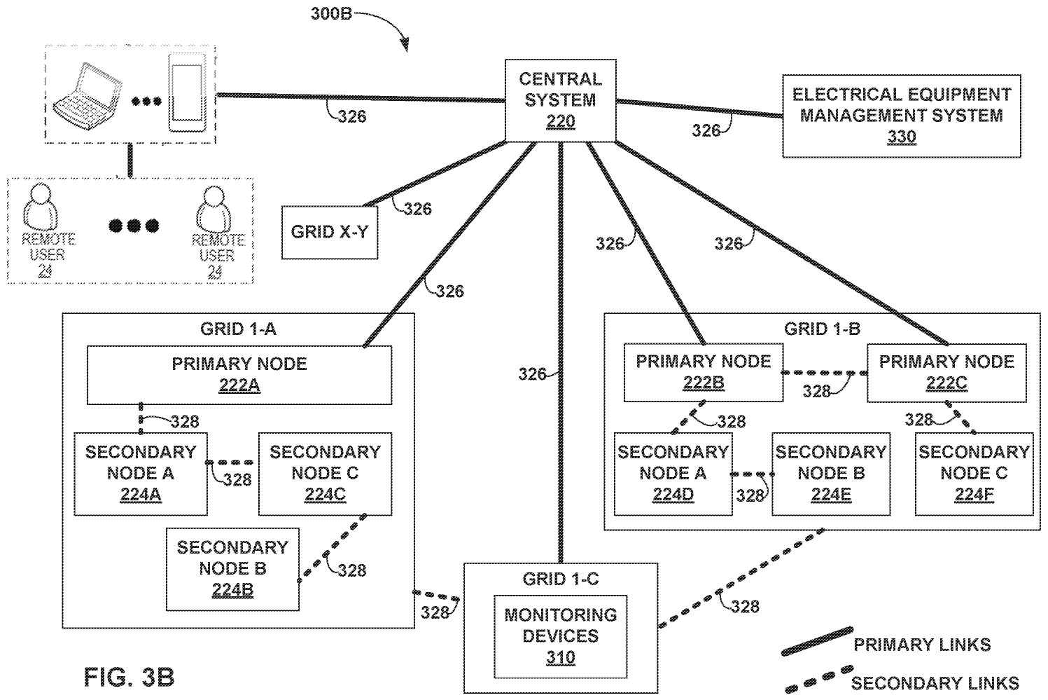

FIG. 3A is a conceptual block diagram of an example electrical-network-monitoring system 300A, which is an example of monitoring systems 214A, 214B of FIGS. 2A and 2B, respectively. In particular, FIG. 3A illustrates a first example data-communication hierarchy within grid-monitoring system 300A, wherein the solid lines 326 indicate direct data connections between primary nodes 222 and the central computing system 220, and wherein the dashed lines 328 indicate “secondary” data links between monitoring nodes 222, 224 and/or additional (e.g., standalone) monitoring and sensing devices 310.

As shown in the example of FIG. 3A, the primary nodes 222 and the secondary nodes 224 are distributed across a power network or power grid such that each secondary node 224 will only communicate data to a primary node 222, and not to another secondary node 224. For instance, in one example configuration, the nodes are distributed across the power grid such that no two secondary nodes 224 are directly adjacent or consecutive along a common stretch of a powerline, e.g., without an intervening primary node 222 located between them to intercept data signals injected into the powerline by the secondary nodes 224. Additionally or alternatively, the secondary nodes 224 may be configured to enable data-transmission capabilities (e.g., injection of signals into the powerline for transmission), but not data-receiving capabilities. In such examples, even in instances in which two secondary nodes 224 are placed consecutively along a common powerline, the second secondary node will not “listen” for signals injected into the cable by the first secondary node, and instead, the signal will continue on past the second secondary node until it reaches the most-proximal primary node 222.

By comparison, in the example monitoring system 300B depicted in FIG. 3B, secondary nodes 224 are configured to communicate data directly with primary nodes 222 (as in FIG. 3B), or, additionally or alternatively, through a subsequent secondary node 224. For instance, in some examples, a secondary node 224 may be configured to automatically re-broadcast any information that the secondary node 224 detects or extracts from within the powerline.

In either example, the distributed monitoring-node hierarchies described in this disclosure provide the practical application of a corresponding data-processing hierarchy. For instance, each of central computing system 220, primary monitoring nodes 222, and secondary monitoring nodes 224 may include varying levels of processing capabilities, such as internal processing circuitry or processor(s). For instance, as detailed further below, primary nodes 222 and/or secondary nodes 224 may include limited internal processing circuitry (also referred to herein as “primary electronics” of the node), capable of low-level, local analytics of detected or received data. Some non-limiting, illustrative examples of local analytics that may be performed by processing circuitry of primary nodes 222 and/or secondary nodes 224 may include, but are not limited to, voltage and current monitoring, capturing, and analytics: partial-discharge monitoring, capturing, and analytics; temperature monitoring and analytics of an electronic device or of nearby components: distance-to-fault determination (e.g., relative to a known location of a node); voltage and current waveform-anomaly capture and analysis: fault indication and diagnostics; incipient-fault detection and analysis; load-balance measurements; reactive and active power measurements and analysis; phasor measurement and analysis: asset-health risk assessment; asset-health failure prediction; fault-direction analysis; and monitoring-node synchronization.

By performing one or more of these types of lower-level analytics locally at monitoring nodes 222, 224, computing resources of the central computing system 220 are conserved to perform higher-level (e.g., more computationally intensive) monitoring and alerting functionality. For instance, central computing system 220 may include processing circuitry configured to perform, as non-limiting examples; powerline-operability-state estimation; faulted-segment identification; fault-response determination; precise-fault-location determination; synchrophasor measurement; conservation-voltage reduction; voltage control; predictive maintenance; asset-risk assessment; load profiling; waveform-anomaly classification and learning; asset-failure prediction; network-connectivity analysis; metering; feeder reconfiguration; and/or safety-alert generation.

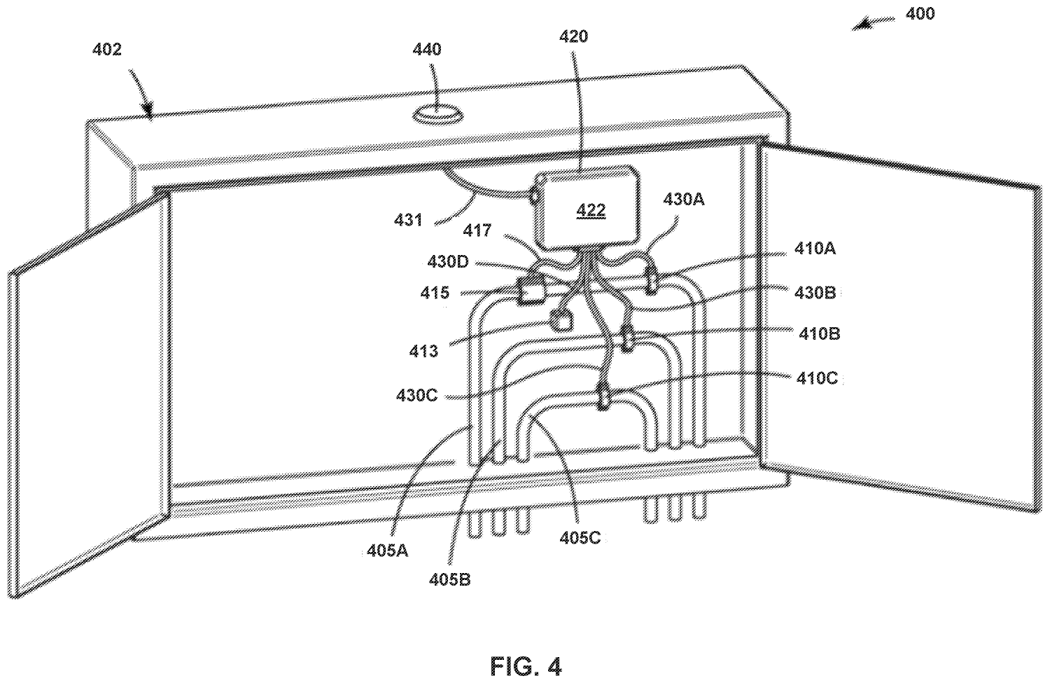

FIG. 4 is a schematic view of one example configuration for a portion of a an electrical-network-monitoring system 400, which is an example of monitoring system primary monitoring node 400, which is an example of monitoring systems 214, 300 of FIGS. 2A-3B. In particular, FIG. 4 illustrates an example enclosure or housing 402 for a primary monitoring node 420, which is an example of any of primary monitoring nodes 222 of FIGS. 2A-3B.

In some examples, primary nodes 420 may be implemented as underground communication devices, as described in commonly assigned U.S. Patent Application number 9,961,418 (incorporated by reference in its entirety herein). By contrast, in the example configuration depicted in FIG. 4, primary node 420 includes a pad-mounted data-communication system configured to be positioned in an above-ground environment, such as where low, medium, or high-voltage cables enter from the underground and are exposed within the grade-level equipment.

For example, primary node 420 may include one or more sensor(s) 410A-410C, e.g., operatively coupled to cable splices, and a transceiver housed an above-ground transformer enclosure 402. Some example grade-level or above-ground devices that can utilize one or more of these primary nodes 420 include, e.g., power or distribution transformers, motors, switch gear, capacitor banks, and generators. In addition, one or more of these monitoring-and-communication systems 400 can be implemented in self-monitoring applications such as bridges, overpasses, vehicle-and-sign monitoring, subways, dams, tunnels, and buildings.

As described above, the primary monitoring devices 420 themselves, or in combination with a sensored analytics unit (SAU), can be implanted in electrical systems requiring low-power computational capabilities driven by, e.g., event occurrences, event identifications, event locations, and event actions taken via a self-powered unit. Further, an integration of GPS capabilities along with time-synchronization events leads to finding key problems with early detection with set thresholds and algorithms for a variety of incipient applications, faults, or degradation of key structural or utility components. Another variable is non-destructive mechanical construction, which could be utilized in fairly hazardous applications.

FIG. 4 illustrates one non-limiting example of such an enclosure or housing 402 for a primary monitoring node 420 that can be implemented at-grade or above-ground. In this example implementation, enclosure 402 houses one or more electrical lines, such as electrical lines 405A-405C (carrying. e.g., low, medium, or high-voltage electrical power). In other examples, enclosure 402 could house a capacitor bank, motor, switch gear, power or distribution transformer, a generator, and/or other utility equipment.

Enclosure 402 also includes at least one primary monitoring node 420 disposed therein, which can monitor a physical condition of the vault or of the components or equipment located in the vault. For example, in this example, a current sensor (410A-410C), such as a Rogowski coil, that produces a voltage that is proportional to the derivative of the current, is provided on each electrical line 405A-405C. Additionally, an environmental sensor 413 can also be included. Other sensor devices, such as those described above, can also be utilized within enclosure 402.

Raw data signals can be carried from the sensors via signal lines 430A-430C to sensored analytics unit (SAU) 422 of primary node 420. The SAU 422 can be mounted at a central location within the enclosure 402, or along a wall or other internal structure. The SAU 422 includes processing circuitry, such as a digital-signal processor (DSP) or system-on-a-chip (SOC) to receive, manipulate, analyze, process, or otherwise transform such data signals into signals useable in a supervisory control and data acquisition (SCADA) system (e.g., central computing system 220 of FIGS. 2A-3B). In addition, the DSP can perform some operations independently of the SCADA. For example, as described above, the DSP of primary monitoring node 420 can perform fault detection, isolation, location and condition monitoring and reporting. Moreover, the DSP/SAU can be programmed to provide additional features, such as, for example, Volt, VAR optimization, phasor measurement (synchrophasor), incipient fault detection, load characterization, post-mortem event analysis, signature-waveform identification and event capture, self-healing and optimization, energy auditing, partial discharge, harmonics/sub-harmonics analysis, flicker analysis, and/or leakage current analysis.

In addition, the DSP and other chips utilized in SAU 422 can be configured to require only low power levels, e.g., on the order of less than 10 Watts. In this aspect, SAU 422 can be provided with sufficient electrical power via a power-harvesting coil 415 that can be coupled, via power cable 417, to one of the electrical lines 405. In addition, the SAU 422 can be implemented with a backup battery or capacitor bank (not shown in FIG. 4).

Processed data from SAU 422 can be communicated to computing system 220 (e.g., a computing network or SCADA) via a transceiver 440. In this aspect, transceiver 440 can include fully integrated, very-low-power electronics (e.g., an SOC for detecting time-synchronous events), along with GPS and versatile radiocommunication modules. Transceiver 440 can be powered by a powerline power source within the enclosure 402, a battery source, or via wireless power (such as via a wireless power transmitter, not shown). SAU 422 can communicate to the transceiver 440 via direct connection with a copper cable and/or fiber cabling 431.

In this example, the transceiver 440 can be mounted directly onto the top (or other) surface of the enclosure 402. The transceiver 440 can communicate with internal enclosure components, such as the SAU 422, via cables 430A-430C. The transceiver 440 can perform network connection, security, and data-translation functions between the outside and internal networks, if necessary.

In another aspect, SAU 422 of primary monitoring node 420 can be configured as a modular or upgradeable unit. Such a modular unit can allow for dongle or separate module attachment via one or more interface ports. As shown in FIG. 4, multiple sensors (410A-410C, 413) are connected to SAU 422. Such a configuration can allow for the monitoring of powerlines and/or a variety of additional environmental sensors, similar to sensor 413, which can detect parameters such as gas, water, vibration, temperature, oxygen-levels, etc.). For example, in one alternative aspect, sensor 413 can comprise a thermal-imaging camera to observe a temperature profile of the environment and components within the enclosure. The aforementioned DSP/other chips can provide computational capabilities to interpret, filter, activate, configure, and/or communicate to the transceiver 440. Dongle or connector blocks can house additional circuitry to create an analog to digital front end. The dongle or connector blocks can also include a plug-n-play electrical circuit for automatically identifying and recognizing the inserted sensing module (and automatically set up proper synchronization, timing, and other appropriate communication conditions).

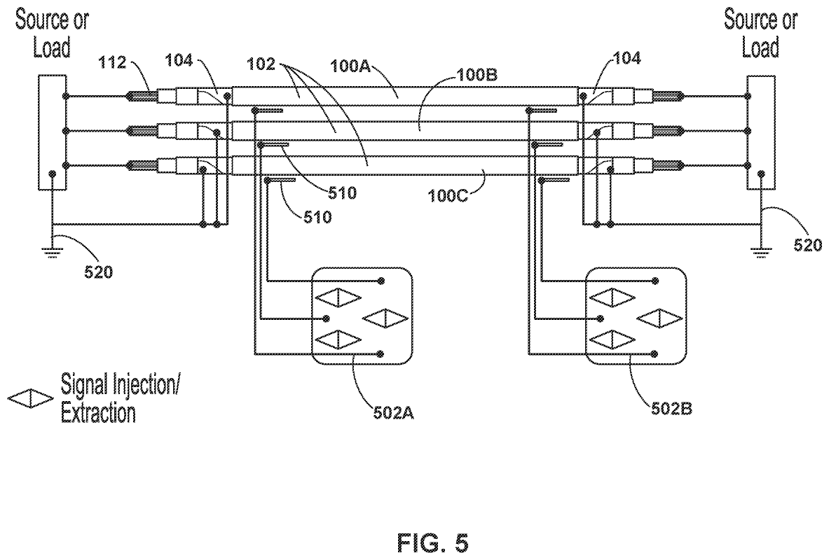

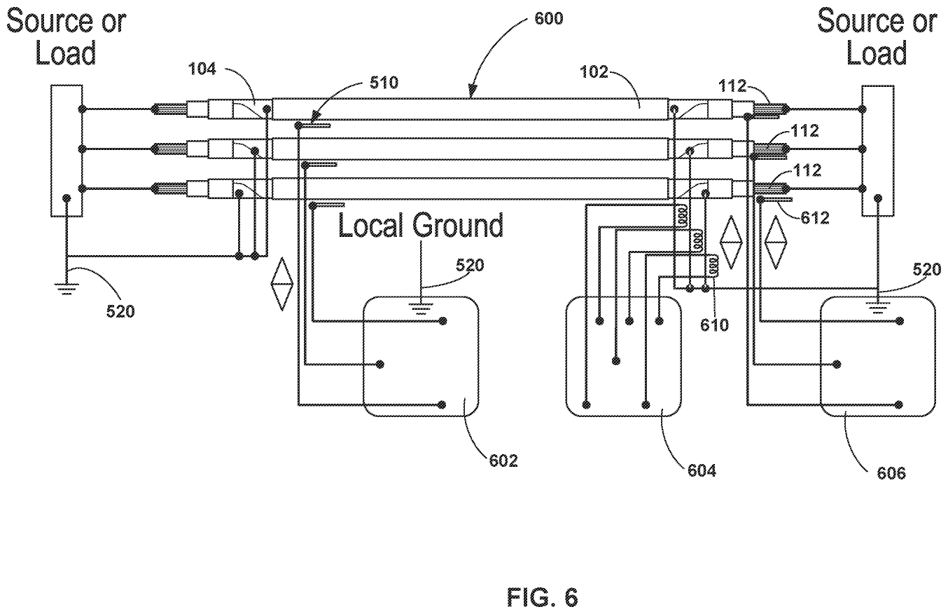

FIGS. 5 and 6 illustrate example implementations of powerline-communication techniques that primary nodes 222 and/or secondary nodes 224 may use to directly transmit and receive data with other nodes of a power-network system. For instance, as described above, secondary monitoring nodes 224 may have reduced or more-limited data-communication capabilities compared to primary monitoring nodes 222, such that, in some cases, secondary monitoring nodes 224 may only be configured to communicate data to other nodes through the powerline to which the respective secondary node 224 is coupled. Accordingly, FIGS. 5 and 6 illustrate techniques for operatively coupling the monitoring nodes to an electric powerline, such that the monitoring nodes may inject signals into the powerline and extract signals from the powerline. However, the examples shown in FIGS. 5 and 6 are merely exemplary of applications for enabling powerline communications. In other examples, secondary monitoring nodes 224 of this disclosure may be operatively coupled to a powerline through other techniques.

In examples of this disclosure, a retrofittable monitoring device 502, which may be an example of primary monitoring nodes 222 or secondary monitoring nodes 224 of FIGS. 2A-3B, includes a coupling layer 510 that can support the other functionalities that either inject or extract “intentional” signals or those that extract “unintentional” or “native” signals (e.g., partial discharge signals) that can be indicative of impending failure of the cable 100. Intentional signals that support the functionalities above include pulses or chirps that can help characterize the powerline (e.g., time-domain retroreflectometry (TDR) or frequency-domain retroreflectometry (FDR)) or time-synchronization signals that synchronize timing between one location and another. Unintentional or native signals of interest on the powerline include the AC waveform and anomalies embedded within the AC waveform, or partial discharges (PDs), for example. In addition, because both native and intentional signals are subject to noise interference, a coupling mechanism that eliminates at least some noise is beneficial.

In general, the example systems, devices, and/or techniques described herein can provide a retrofittable coupling mode for cable 100 that can support communication along cable 100 to other parts of a network: a coupling that can support various functionalities for infrastructure monitoring where intentional signals are injected and/or extracted and native signals are extracted: a coupling method that reduces noise; combinations of the retrofit cable communication capability with at least one function and noise reduction; and/or a coupling that supports more than one function.

The signals described herein, including both unintentional native signals (e.g., PD) and intentional signals (e.g., communication signals), may typically include radiofrequency (RF) signals, which lie in the frequency range of about 0.1 to about 10 MHz. Within this frequency range, cable 100 can be considered as a coaxial transmission line, that includes a central conductive core 112, a dielectric insulating layer 108, and a coaxial conducting shield 104 being grounded at one or both of the cable ends. In such a system, at a distance far enough from the ends, the electric potential on both the core conductor 112 and the shield 104 will oscillate relative to ground. Consequently, the signal may be detected by capacitively coupling to the shield 104, e.g., by wrapping a conducting layer 510 (e.g., a conductive metal foil) over the cable jacket 102, thereby creating a coupling capacitor that includes the shield 104, the jacket dielectric 102, and the conducting layer 510.

In examples described herein, a primary or secondary monitoring node may be operatively coupled to a powerline via either a “single-ended” coupling technique or via a “differential” coupling technique. In a single-ended coupling technique, the monitoring node is capacitively or inductively coupled to an electrical cable at one end (e.g., to the cable shield 104 or to the central conductor 112 of the cable), and coupled to a local ground 520 at the other end. In some such examples, the monitoring node is configured to detect an RF signal within the electrical cable by measuring (e.g., via an RF amplifier of the monitoring node) the potential difference between the cable and the local ground 520. In other such examples, the monitoring node is configured to detect the RF signal within the electrical cable by measuring (e.g., via a current amplifier of the monitoring node) the current running through the cable coupling. In the present description, such implementations are referred to as “single-ended.”

In a differential coupling technique, such as the example illustrated in FIG. 5, a primary or secondary monitoring node 502 is operatively coupled (e.g., inductively or capacitively) to two different cables 100 of a powerline (e.g., via the cable shields 104 or via the central conductors 112). In the non-limiting example shown in FIG. 5, the monitoring node 502 is physically coupled (via coupling layer 510) to the outer jackets 102 of cables 100, and capacitively coupled (via coupling layer 510) to the cable shields 104 located underneath the jackets 102. If three cables 100A-100C are available, then there are three potential cable pairs (100A, 100B), (100B, 100C), and (100A, 100C) across which monitoring node 502 may be coupled. In multi-cable cases having a number “n” of cables 100 wherein n>3, then there are n*(n−1)/2 unique possible combinations of cable pairs (e.g., any pair of two cables) that may be selected from among the n cables 100, or in other words, choosing 2 cables out of n cables, commonly referred to in combinatorial mathematics as “n choose 2,” or “n-nCr-2”). The communication signal can be multiplexed or repeated on these multiple pairs. This signal can be extracted from a similarly coupled communication device located at a remote location. Each device 502 can sense locally and communicate information or can act as a repeater to send the information along, or act as a concentrator to collect the information and then send the information to a central location.

As shown in FIG. 5, a device 502 may be capacitively coupled to at least two separate cables (e.g., 100B, 100C) associated with two different phases. These cables 100B, 100C can be of the same three-phase group or can be unrelated single phases. A voltage or current amplifier (e.g., node 502A) may then be connected between the two coupling capacitors 510, thus measuring the potential difference or the current flowing between them. Such an implementation does not require an independent ground, and so entails a “floating” installation that can be easily coupled onto the cable system. Furthermore, a differential approach will be insensitive to any common-mode noise picked up by the system. For example, in a three-phase system (FIGS. 5 and 6), the three cables 100A-100C are laid as a bundle, and accordingly, the cables will pick up approximately the same electromagnetic noise, which a differential setup will then reduce or cancel out. Similarly, if the phases are not in the same three-phase system, the cables can also have similar pick-up.

Another feature of the capacitive coupling to the cable shield 104 is that this approach allows a straightforward approach to inject RF signals into the cable system, e.g., by applying an RF voltage between the coupling capacitor and the ground 520, e.g., for a single-ended system, or differentially between cable pairs. The injected signals may be received similarly to the method used for native signals, as described above. The injection and pickup of such intentional signals may be used for various purposes, such as: communication between devices: time synchronization between devices; time-domain reflectometry (TDR) or frequency-domain reflectometry (FDR) to detect and localize defects, faults and structural changes in the cable system; channel characterization (e.g., frequency dependent loss, propagation delay); and grid configuration/mapping.

In addition, intentional signals may be injected into more than one channel. e.g. into two or more cables 100 or cable pairs. Such a multichannel approach allows an increased communication bandwidth and/or enhanced communication reliability.

In some examples, monitoring nodes 502 (e.g., primary nodes 222 and/or secondary nodes 224) may include or may be current amplifiers. For instance, current amplifiers may be used for coupling, where two capacitors 510 on each cable 100 are capacitively coupled to the shields 104, e.g., via physical coupling of a foil layer 510 onto outer jackets 102. Such examples require separate pairs of capacitors per differential channel, thus preventing unwanted signal leakage between the channels. An alternative is to use one capacitor 510 (e.g., conductive foil layer) for each power cable 100 with a high-impedance voltage amplifier (rather than a low-impedance current amplifier) where multiple amplifiers can connect to each foil capacitor 510.

FIG. 6 is a schematic diagram of another example differential coupling system 600 according to techniques of this disclosure. FIG. 6 depicts a more general example of differential or single-ended capacitive coupling to cable shields 104, and also other couplings on the same line or lines to extract or inject other signals of interest (e.g., a communication signal). This other coupling can be single-ended (ground reference) or differential (reference to another voltage).

For instance, FIG. 6 depicts three example cable-monitoring devices 602, 604, and 606. Cable-monitoring device 602 is capacitively coupled to cable shield 104, via a physical coupling 510 overtop of cable jacket 102 (or a cable splice, if present). Cable-monitoring device 602 is an example of a differential or single-ended functional device.

Cable-monitoring device 604 is inductively coupled to cable shield 104, via a physical connection 610 to a wired connection to a local ground 520. Cable-monitoring device 604 is an example of a device that is differential between phases, or a “differential-one-phase-each (DOPE)” functional device.

In some instances, any two (or more) nodes 602, 604, 606, each of which may be an example of a primary node 232 or a secondary node 234, may locally communicate (e.g., via direct powerline communication) a set of data that is necessary for making a “shared” decision or measurement. As used herein, a “shared measurement” refers to a measurement of a signal (and associated analytics) that is indicative of a condition commonly shared by two or more nodes and/or a section of cable located directly between the two or more nodes. Similarly, a “shared decision” refers to a determined action that affects a condition commonly shared by two or more nodes and/or a section of cable located directly between the two or more nodes. The shared decision may be determined based on, or in response to, a shared measurement.

For instance, nodes 602 and 604 may be configured to, when necessary, directly exchange information in order to localize the origin of a partial-discharge signal along a section of the shared cable 600 that is directly in between nodes 602, 604. In such examples, the data analysis (e.g., the PD-localizing) may be performed locally on any or all of the nodes, such that the “raw” data does not need to be transmitted to central computing system 220, thereby increasing available bandwidth resources along both a specific datalink (e.g., between a primary node 232 and the central computing system 220) as well as across the large-scale power network as a whole. In some examples, a primary or secondary monitoring node may be configured to locally monitor or “track” cable parameters, without reporting the sensed data to other nodes or the central computing system, unless and until the node identifies an above-threshold change in the monitored parameter, thereby further conserving transmission bandwidth and “upstream” processing power.

In some examples, primary and secondary monitoring nodes of the powerline monitoring system are configured to perform cable diagnostics. For instance, any of nodes 602, 604, 606 may be configured to inject a signal into cable 600. The signal may either be reflected back to the originating node, or may be transformed within cable 600 and received at a different node. In either case, the receiving node may use the received signal to assess certain parameters or characteristics of cable 600, such as (but not limited to) a condition (e.g., age-based deterioration) of insulation layer 108 (FIG. 1A), the presence of any defects in the conductor 112, or the locations of joints, taps, or faults within cable 600.

By using this type of injected-signal technique (or other methods, such as auto-correlation of native signals) the powerline monitoring system can determine both general system health and local cable health. As used herein, the “health” can refer to a general condition of the cable (e.g., without reference to a particular anomaly at a particular location along the cable), or in other examples, can refer to the health of the cable at a particular site or in a defined section of the cable that is being sampled via the injected signal.

Some non-limiting examples of health-related cable-monitoring through intentional signal injection include identifying fault-based conductor breaks in conductor 112, damage or breaks to the outer shield layer 102 (e.g., due to animals, corrosion, digging, etc.), the presence of water-uptake at or near insulation 108, local temperature increases and/or associated damage, and other irregularities. Because many of these examples may include relatively slowly emerging conditions, the primary and/or secondary monitoring nodes described herein may be configured to perform ongoing periodic or continuous monitoring to identify condition changes over time. Additionally, as described above, the distributed hierarchy of primary-and-secondary-node techniques of this disclosure allow for a highly dense coverage of a power system with monitoring nodes; accordingly, may of these local-cable-monitoring techniques through intentional signal injection may be performed with even higher precision and/or accuracy.

In some examples, the primary and secondary monitoring nodes 602, 604, 606 of the powerline-monitoring system may be configured to perform “mapping” of the power network. For instance, the powerline-monitoring system may determine whether node 602 is operatively coupled to the same cable 600 as node 604, e.g., by injecting a unique signal into cable 600 at node 602 and determining which other nodes 604, 606 detect the signal.

Additionally or alternatively, the powerline-monitoring system (e.g., either at central computing system 220, or via processing circuitry of any of the individual nodes) may compare detected voltage and/or current spikes, or other similar detected anomalies, between any two nodes to determine whether the two nodes are coupled to the same cable 600. In some such examples, the system may additionally be configured to estimate (e.g., map) a physical distance between the two nodes, e.g., if the two nodes are internally synchronized and both the signal-propagation velocity and a time delay (e.g., duration between detection at each node) are known.

In other examples, e.g., in which the physical distance between two nodes and the signal “time of flight” (e.g., transmission duration) are known, the powerline-monitoring system can determine a propagation delay between the two nodes, any or all of which may then be used for both general-level cable-health analytics, local cable-health analytics.

For instance, any or all of an electrical impedance of cable 600, the signal-propagation velocity, and the time-of-flight of the signal between the two nodes may be dependent on the dielectric constant of insulation layer 108, which may change over time due to deterioration or damage to the insulation layer. Accordingly, the powerline-monitoring system may use local intentional signal-injection techniques (e.g., using either a reflected signal for a single monitoring node, or using a transmitted signal between two monitoring nodes), to determine these types of characteristics of cable 600, which may be used as a proxy for the dielectric constant of the insulation layer 108 to monitor the general health of cable 600.

Additionally or alternatively to the general-health analytics techniques described in the previous example, the powerline-monitoring system may use similar techniques to perform local-cable-health analytics. For example, in scenarios in which the powerline-monitoring system identifies the presence of a defect or other local damage to cable 600, the system can determine an approximate location of the defect, e.g., either by measuring the physical distance to the defect or by measuring the time-of-flight of an injected signal to that defect. In some examples, if the propagation velocity can be established on the cable (by knowing the time of flight and the actual distance for one or more particular structures like a termination point), then the distance to a defect can be estimated so that corrective action can be taken.

Additionally or alternatively to any of the above examples, similar (e.g., intentional-signal-injection-based) techniques may be used to determine any or all of an electrical impedance of cable 600, a physical length of cable 600 or subsections thereof, and the “branching” of cable 600 (e.g., via mapping, as described above). The powerline-monitoring system may then use these parameters to produce a virtual simulation (or “digital twin”) of an electrical power system (e.g., the power network or power grid that includes cable 600).

Similarly, the powerline-monitoring system may use intentional signal injection via node(s) 602, 604, 606 to synchronize the various nodes of the system. For instance, the system may inject, via any of the primary or secondary nodes, intentional signals such as “pulses” or “chirps” to perform time-domain retroreflectometry (TDR) or frequency-domain retroreflectometry (FDR), or other similar time-synchronization signals that synchronize timing between two or more monitoring nodes. In various examples, the system may be configured to use individual (e.g., relative) timing signals, or in other examples, maintain a universal clock for all nodes 602, 604, 606.

In the example shown in FIG. 6, cable-monitoring device 606 is capacitively coupled (via coupling 612) directly to central conductor 112, or adjacent to central conductor 112. Cable-monitoring device 606 is an example of a single-ended functional device (and either of primary monitoring nodes 222 or secondary monitoring nodes 224). This type of coupling 612 directly to central conductor 112 may be achieved through the use of an intermediary connector device, as described and illustrated with respect to FIGS. 7A-7F.

For instance, FIGS. 7A-7F are six illustrative examples of secondary monitoring nodes of a power-network-monitoring system, in accordance with techniques of this disclosure. In particular, each of FIGS. 7A-7F includes a block diagram illustrating an example arrangement of sub-components of a secondary monitoring node, as well as a schematic view of an example coupling mechanism for operatively coupling the respective secondary monitoring node to an electric powerline of a power network or grid. For example, FIGS. 7A-7F illustrate secondary monitoring nodes 724A-724F, respectively, each of which is an example of secondary monitoring nodes 224 of FIGS. 2A-3B.

FIG. 7A includes a block diagram illustrating a first example arrangement of sub-components of secondary monitoring node 724A, where the arrangement of sub-components is configured to electrically couple a set of “functional” sub-components 702 to an article of electrical equipment 704 of a power-delivery system. As shown in FIG. 7A, the functional sub-components 702 of secondary node 724A include one or more of a voltage-sensing unit 706, a data-acquisition unit 708, a data-processing-and-storage unit 710 (e.g., processing circuitry), a “secondary” communication unit 712, and a capacitive-power-harvesting-and-power-management (CPHPM) unit 714. The functional sub-components 702 are generally configured to receive and process signals generated by various sensors of secondary monitoring node 724A. As shown in FIG. 7A, these various sensors may include one or more of ground sensors 716, electrical-current sensors 718, environmental sensors 720, or other sensors 722.

In some examples, the functional sub-components 702 (and/or other adjacent devices 726) may additionally receive electrical power from other power harvesters 728. e.g., other than via a coupling to a component 704 of the power network. For instance, as shown in FIG. 7A, secondary node 724A includes a high-voltage capacitive coupling unit 730 configured to electrically couple the functional sub-components 702

In accordance with techniques of this disclosure, secondary monitoring node 724A is removably coupled to a component 704 of an electric-power network via a separable T-body connector 740. As shown in FIG. 7A, T-body connector 740 includes three ports configured to mutually electrically couple (1) a power cable 100 of an electric powerline; (2) an article of electrical equipment 704, such as a cable splice, cable termination, etc.; and (3) secondary monitoring node 724A. T-body connector 740 further includes a ground connection 742 to an electrical ground 744, e.g., of electrical equipment 704.

FIG. 7B includes a block diagram illustrating a second example arrangement of sub-components of secondary monitoring node 724B, which is an example of secondary monitoring node 724A of FIG. 7A, except for the differences noted herein. In particular, FIG. 7B illustrates that, instead of T-body connector 740 of FIG. 7A, secondary monitoring node 724B is electrically coupled to electrical equipment 704 and power cable 100 via a removable elbow-type connector 750. For instance, unlike the more-rigid T-body connector 740, elbow connector 750 may include a hinge 752 allowing for modification of an angle between the electrical couplings of equipment 704, power cable 100, and secondary monitoring node 724B. As used herein, “removable” refers to the property that elbow connector 750 is not rigidly coupled to electrical equipment 704. In some examples, but not all examples, secondary monitoring node 724B may be rigidly electrically coupled to elbow connector 750 via a port 754 on a backside of elbow connector 750.

FIG. 7C includes a block diagram illustrating a third example arrangement of sub-components of secondary monitoring node 724C, which is an example of secondary monitoring node 724A of FIG. 7A and/or node 724B of FIG. 7B, except for the differences noted herein. In particular, FIG. 7C illustrates an example in which secondary monitoring node 724C is physically separable into at least two distinct components: a plug 760 and an end cap 770.

In the example shown in FIG. 7C, the primary electronics 710 (e.g., processing circuitry and memory) and sensors 748 of secondary node 724C are housed within plug 760, configured to removably and electrically couple (e.g., via high-voltage connection 738) to one of the three coupling ports of T-connector 740 of FIG. 7A. A backside of plug 760 includes two coupling ports: a low-voltage connection port 736, and an external-connections port 746A for coupling secondary node 724C to other devices (e.g., external sensors, etc.). Low-voltage connection port 736 additionally functions as an electrical “test point.” enabling a user to connect an external device (e.g., a voltmeter or other device) to determine (via activation of the connected device) whether power cable 100 is currently energized while plug 760 is coupled to the T-connector 740.

Secondary monitoring node 724C further includes a removable end cap 770 configured to fit over a back side of plug 760. In the example depicted in FIG. 7C, end cap 770 is configured to cover (e.g., prevent access to) low-voltage connection port 736 while coupled to plug 760. By comparison, end cap 770 includes an external electrical connection 746B configured to electrically couple to external electrical connection port 746A of plug 760. External electrical connection 746B is routed through end cap 770, such that external electronic devices may still be electrically connected to plug 760 while end cap 770 is removably coupled to plug 760.

FIG. 7D includes a block diagram illustrating a fourth example arrangement of sub-components of secondary monitoring node 724D, which is an example of secondary monitoring nodes 724A-C of FIGS. 7A-C, respectively, except for the differences noted herein. Similar to the example depicted in FIG. 7C, external connections 746B of secondary monitoring node 724D may be routed through end cap 770. However, unlike plug 760 of FIG. 7C, which is depicted as a single, physically coherent unit, secondary node 724D of FIG. 7D includes plug 760A and a removable extension module 760B. In this example, the primary electronic coupling mechanism (for coupling to T-connector 740) is housed within plug 760A; however, the actual “functional” sub-components 702 of secondary node 724D are housed within extension module 760B, which functions as an intermediary coupling component between electrical-connector plug 760A and end cap 770.

FIG. 7E includes a block diagram illustrating a fifth example arrangement of sub-components of secondary monitoring node 724E, which is an example of secondary monitoring nodes 724A-D of FIGS. 7A-D, respectively, except for the differences noted herein. For instance, similar to the example plug 760A depicted in FIG. 7D, the primary electronic coupling mechanism 738 (for electronic coupling to T-connector 740) is housed within removable plug 760C. However, unlike the example secondary node 724D of FIG. 7D, in which functional sub-components 702 are housed within a removable extension module 760B, in the example secondary node 724E depicted in FIG. 7E, functional sub-components 702 (including primary electronics 710 and sensors 748) are housed within end cap 770A, which is an example of end cap 770 of FIGS. 7C and 7D.

FIG. 7F includes a block diagram illustrating a sixth example arrangement of sub-components of secondary monitoring node 724F, which is an example of secondary monitoring nodes 724A-E of FIGS. 7A-E, respectively, except for the differences noted herein. For instance, secondary monitoring node 724F includes the same example electrical-connector plug 760A depicted in FIG. 7D. Additionally, similar to the examples shown in FIGS. 7C and 7E, end cap 770B is configured to couple directly to electrical-connector plug 760A. However, unlike the previous examples, in the example shown in FIG. 7F, the primary electronics 710 (e.g., processing circuitry and memory) of secondary node 724F are housed within a processing module 780 that is both, physically distinct from plug 760A and end cap 770B, but also not configured to physically interconnect with either device. Instead, processing module 780 may be configured to receive signals and data, from an external sensor module (not shown), e.g., via short-range wireless communication capabilities, or via a wired connection through external connections port 746A. After processing or analyzing the data, processing module 770B may then transmit the processed data, e.g., via short-range wireless communication capabilities, or via a wired connection through external connections port 746A, to plug 760A for signal injection into cable 100.

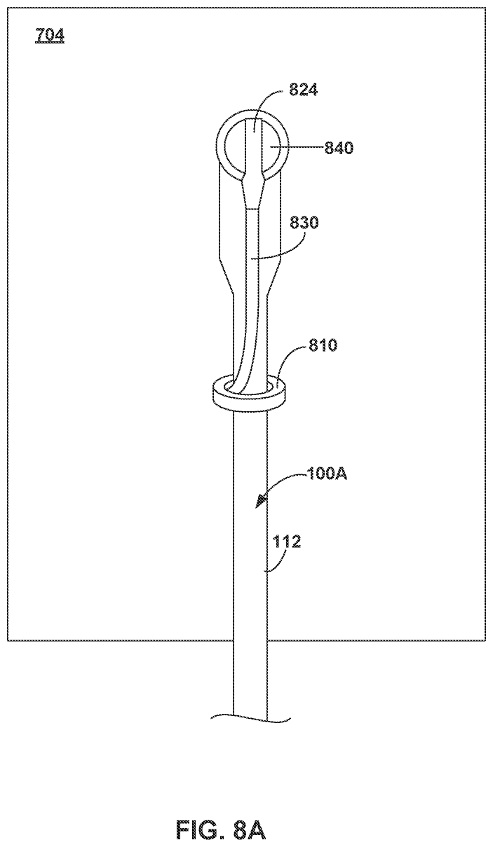

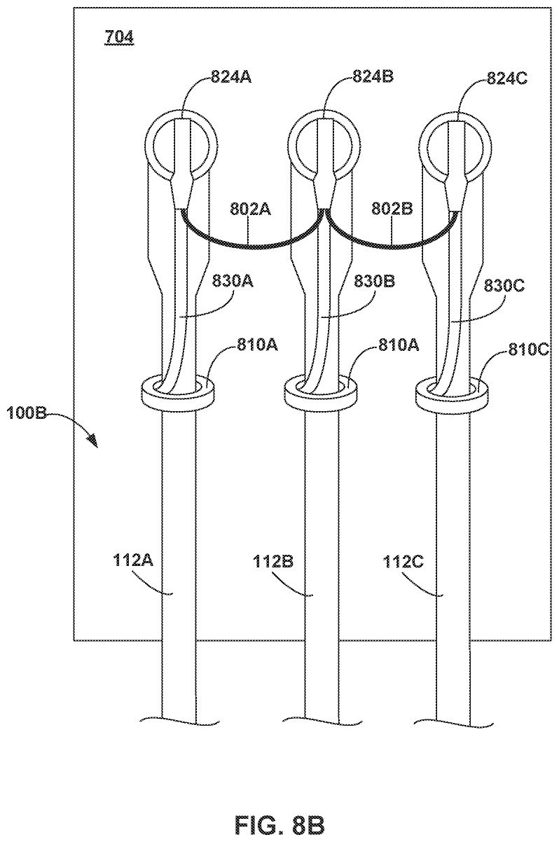

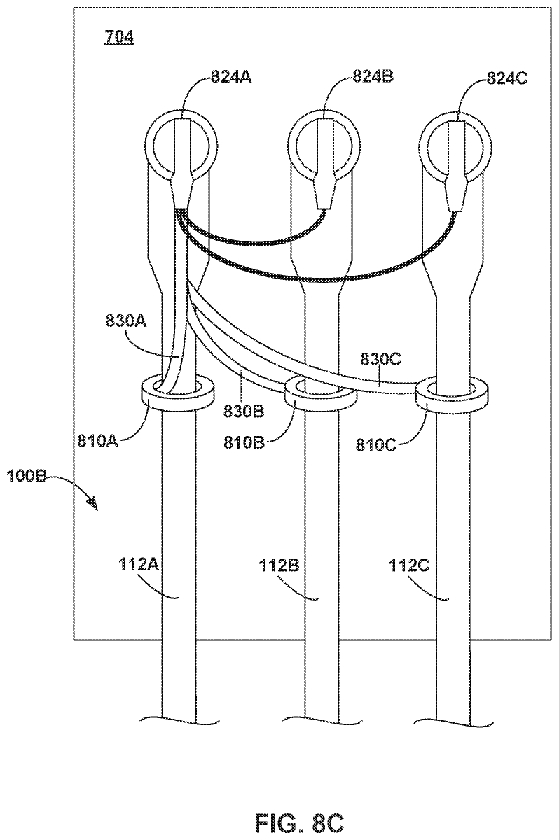

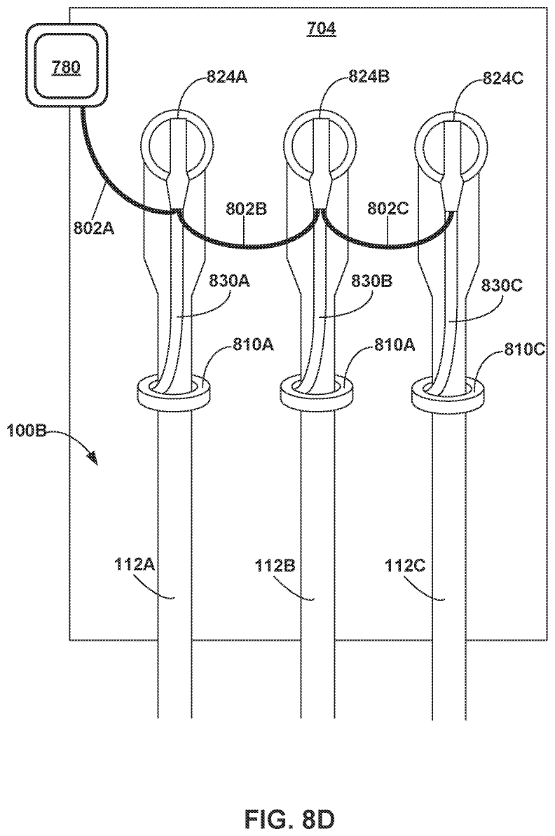

FIGS. 8A-8D illustrate four non-limiting examples of techniques for operatively coupling and/or interconnecting one or more secondary monitoring nodes 824 to different phases of a single electric power cable. For instance, FIG. 8A illustrates a first example technique applied with respect to a single-phase electric-power cable 100A (FIG. 1A), e.g., having only a single central conductor or phase 112. Accordingly, the powerline-monitoring system in this example includes only a single secondary monitoring node 824, which is an example of secondary nodes 224, 724, above. Similar to the examples depicted in FIGS. 7A-7F, secondary monitoring node 824 is operatively and electrically coupled to both power cable 100A and an article of electrical equipment 704 via a three-port connector 840. Three-port connector 840 may be an example of T-connector 740 of FIGS. 7A and 7C-7F, an example of elbow connector 750 of FIG. 7B, or an example of another similar coupling, such as the capacitive or inductive couplings described above with respect to FIGS. 5 and 6. In the example shown in FIG. 8A, secondary monitoring node 824 further includes a current sensor 810 (e.g., a Rogowski coil) coupled to signal line 830, which are examples of current sensor 410 and signal line 430, respectively, described above with respect to FIG. 4.

FIG. 8B illustrates a second example technique applied with respect to a multi-phase electric-power cable 100B (FIG. 1B), e.g., having three conductors or phases 112A-112C. Accordingly, the powerline-monitoring system in this example includes three distinct secondary monitoring nodes 824A-824C, each secondary monitoring node having its own current sensor 810A-810C, respectively.

In the example depicted in FIG. 8B, the three secondary nodes 824A-824C are locally communicatively coupled to one another. For instance, secondary node 824A shares data with secondary node 824B via data cable 802A, and secondary node 824B shares data with third secondary node 824C via data cable 802B. In this way, monitoring data can be shared between the three phases of cable 100B, e.g., for timing or for communication redundancy. For example, if more than one phase is coupled to the same electronics, the communication can be sent on two or more lines for redundancy, e.g., if a channel is disrupted, or the signal can be distributed on two or more lines.

FIG. 8C illustrates a third example technique applied with respect to a multi-phase electric-power cable 100B (FIG. 1B), e.g., having three conductors or phases 112A-112C. Unlike the example depicted in FIG. 8B, in which an equivalent secondary node 824 is deployed on each phase of the power cable 100B, the example depicted in FIG. 8C includes one “active” secondary node 824A and two “passive” secondary nodes 824A, 824B. That is, secondary node 824A houses the primary electronics (e.g., processing circuitry and memory) that primarily govern and process data for all three secondary nodes 824A-824C. Because active secondary node 824A performs the processing of data collected by current sensors 810A-810C, signal lines 830A-830C are directly connected between active secondary node 824A and each of current sensors 810A-810C.

Additionally or alternatively, active secondary node 824A includes local data connections or other direct couplings 802A, 802B to secondary nodes 824B, 824C, respectively. For instance, although “passive” secondary nodes 824B. 824C may not be configured to perform primary data processing, the nodes may transfer data and/or power with active secondary node 824A for other purposes, such as voltage-sensing, powerline communication (e.g., signal injection and/or extraction), and power-harvesting from the various phases of cable 100B.

FIG. 8D illustrates a fourth example technique applied with respect to a multi-phase electric-power cable 100B (FIG. 1B), e.g., having three conductors or phases 112A-112C. Unlike the example depicted in FIG. 8C, which includes one “active” secondary node 824A and two “passive” secondary nodes 824A, 824B, the example deployment of FIG. 8D includes three “passive” secondary nodes 824A-824C, communicatively coupled to the physically distinct processing module 780 of FIG. 7F.

For instance, similar to the example in FIG. 8C, processing module 780 includes local data connections or other direct couplings 802A-802C to secondary nodes 824A-824C such that passive secondary nodes 824A-824C may perform the more “passive” functions of voltage-sensing, powerline communication (e.g., signal injection and/or extraction).

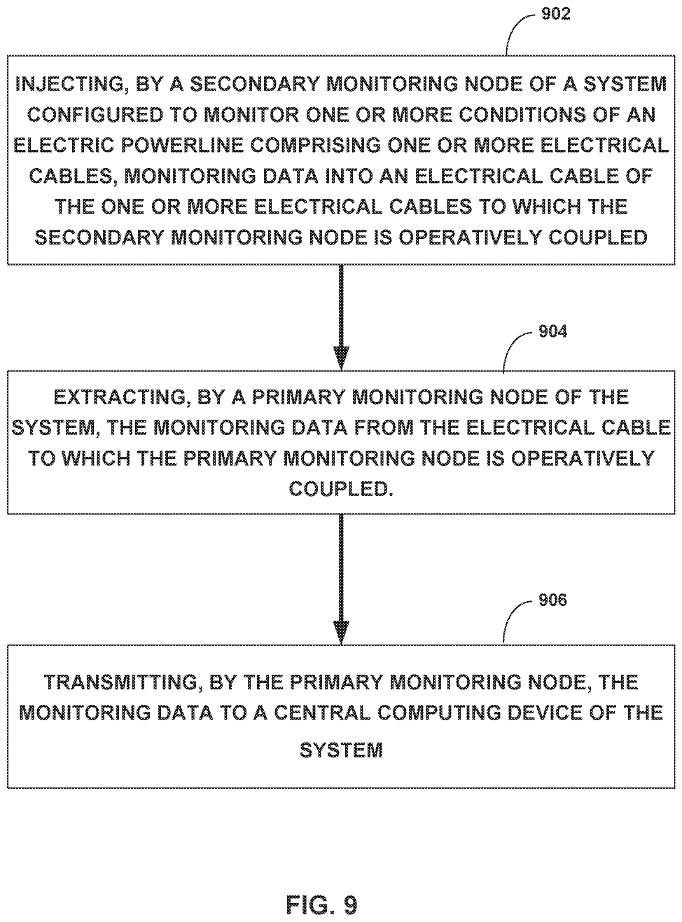

FIG. 9 is a flowchart illustrating example techniques for monitoring an electric power network, in accordance with this disclosure. The techniques of FIG. 9 are described with respect to FIGS. 2A and 2B. The method includes injecting, by a secondary monitoring node 224 of a system 214 configured to monitor one or more conditions of an electric powerline 202 comprising one or more electrical cables 100, monitoring data into an electrical cable 100A (FIG. 1A) of the one or more electrical cables 100 to which the secondary monitoring node 224 is operatively coupled (902).

The method further includes extracting, by a primary monitoring node 222 of the system 214, the monitoring data from the electrical cable 100 to which the primary monitoring node 222 is operatively coupled (904). The method further includes transmitting, by the primary monitoring node 222, the monitoring data to a central computing device 220 of the system 214 (906).

In the present detailed description of the preferred embodiments, reference is made to the accompanying drawings, which illustrate specific embodiments in which the invention may be practiced. The illustrated embodiments are not intended to be exhaustive of all embodiments according to the invention. It is to be understood that other embodiments may be utilized, and structural or logical changes may be made without departing from the scope of the present invention. The following detailed description, therefore, is not to be taken in a limiting sense, and the scope of the present invention is defined by the appended claims.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “proximate.” “distal,” “lower,” “upper,” “beneath.” “below.” “above,” and “on top,” if used herein, are utilized for ease of description to describe spatial relationships of an element(s) to another. Such spatially related terms encompass different orientations of the device in use or operation in addition to the particular orientations depicted in the figures and described herein. For example, if an object depicted in the figures is turned over or flipped over, portions previously described as “below” or “beneath” other elements would then be above or on top of those other elements.

The techniques of this disclosure may be implemented in a wide variety of computer devices, such as servers, laptop computers, desktop computers, notebook computers, tablet computers, hand-held computers, smart phones, and the like. Any components, modules or units have been described to emphasize functional aspects and do not necessarily require realization by different hardware units. The techniques described herein may also be implemented in hardware, software, firmware, or any combination thereof. Any features described as modules, units or components may be implemented together in an integrated logic device or separately as discrete but interoperable logic devices. In some cases, various features may be implemented as an integrated circuit device, such as an integrated circuit chip or chipset. Additionally, although a number of distinct modules have been described throughout this description, many of which perform unique functions, all the functions of all of the modules may be combined into a single module, or even split into further additional modules. The modules described herein are only exemplary and have been described as such for better case of understanding.

If implemented in software, the techniques may be realized at least in part by a computer-readable medium comprising instructions that, when executed in a processor, performs one or more of the methods described above. The computer-readable medium may comprise a tangible computer-readable storage medium and may form part of a computer program product, which may include packaging materials. The computer-readable storage medium may comprise random access memory (RAM) such as synchronous dynamic random-access memory (SDRAM), read-only memory (ROM), non-volatile random-access memory (NVRAM), electrically erasable programmable read-only memory (EEPROM), FLASH memory, magnetic or optical data storage media, and the like. The computer-readable storage medium may also comprise a non-volatile storage device, such as a hard-disk, magnetic tape, a compact disk (CD), digital versatile disk (DVD), Blu-ray disk, holographic data storage media, or other non-volatile storage device.

The term “processor.” as used herein may refer to any of the foregoing structure or any other structure suitable for implementation of the techniques described herein. In addition, in some aspects, the functionality described herein may be provided within dedicated software modules or hardware modules configured for performing the techniques of this disclosure. Even if implemented in software, the techniques may use hardware such as a processor to execute the software, and a memory to store the software. In any such cases, the computers described herein may define a specific machine that is capable of executing the specific functions described herein. Also, the techniques could be fully implemented in one or more circuits or logic elements, which could also be considered a processor.

In one or more examples, the functions described may be implemented in hardware, software, firmware, or any combination thereof. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor”, as used may refer to any of the foregoing structure or any other structure suitable for implementation of the techniques described. In addition, in some aspects, the functionality described may be provided within dedicated hardware and/or software modules. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

It is to be recognized that depending on the example, certain acts or events of any of the methods described herein can be performed in a different sequence, may be added, merged, or left out altogether (e.g., not all described acts or events are necessary for the practice of the method). Moreover, in certain examples, acts or events may be performed concurrently, e.g., through multi-threaded processing, interrupt processing, or multiple processors, rather than sequentially.

In some examples, a computer-readable storage medium includes a non-transitory medium. The term “non-transitory” indicates, in some examples, that the storage medium is not embodied in a carrier wave or a propagated signal. In certain examples, a non-transitory storage medium stores data that can, over time, change (e.g., in RAM or cache).

Various examples have been described. These and other examples are within the scope of the following claims.

1. A system configured to monitor one or more conditions of an electric powerline comprising one or more electrical cables, the system comprising:
at least one primary node operatively coupled to at least one electrical cable of the one or more electrical cables and communicatively coupled to a central computing system; and
at least one secondary node operatively coupled to at least one electrical cable of the one or more electrical cables and configured to communicate data via powerline communication to the at least one primary node, wherein the at least one primary node is configured to deliver the data to the central computing system.

2. The system of claim 1, wherein the data is indicative of at least one of:
a health of a component of the electric powerline;
one or more environmental conditions at the secondary node;
a state or operability of an electrical grid comprising the electric powerline;
a presence of a fault in the electric powerline; or
a location of a fault in the electric powerline.

3. The system of claim 1, wherein the system is further configured to control field devices.

4. The system of claim 1, further comprising a plurality of primary nodes comprising the at least one primary node, wherein respective primary nodes of the plurality of primary nodes are positioned on:
termination points of respective cables of the one or more electrical cables;
branch points of respective cables of the one or more electrical cables;
respective medium-voltage cables of the one or more electrical cables; or
cable accessories of respective cables of the one or more electrical cables.

5. The system of claim 1, wherein the at least one primary node is configured to deliver the data to the central computing system via a wireless data communication, a mesh network, an Ethernet network, or fiber optic cables.

6. The system of claim 1, wherein the data communicated by the at least one secondary node indicates at least one of:
a fault direction;
fault measurements;
fault alerts;
electrical-asset-health alerts;
a partial-discharge magnitude;
a partial-discharge waveform;
a partial-discharge calibration;
partial-discharge statistical information;
partial-discharge-based alerts;
incipient faults;
a temperature;
cable diagnostic signals;
a current waveform or a voltage waveform;
waveform-based alerts;
relative current phase information and relative voltage phase information;
a current magnitude and current phase;
a voltage magnitude and voltage phase;
an impedance;
power-quality measurements;
load measurements;
an amount of reactive power or active power;
an estimated distance between the at least one secondary node and a detected fault, a detected partial-discharge event, or a waveform anomaly;
relative time references or absolute time references;
an identifier for the at least one secondary node;
actuation and control signals; or
timing or synchronization signals.

7. The system of claim 1, wherein at least one of the at least one primary node or the at least one secondary node comprise processing circuitry configured to:
perform voltage and current monitoring, capturing, and analytics;
perform partial-discharge monitoring, capturing, and analytics;
perform temperature monitoring and analytics of an electronic device or of nearby components;
determine a distance to an electrical fault;
capture and analyze a voltage-waveform anomaly or a current-waveform anomaly;
determine an electrical fault;
detect and analyze an incipient fault;
measure a load-balance of the electric powerline;
measure and analyze active power and reactive power of the electric powerline;
measure and analyze a phasor;
assess an asset-health risk;
predict a failure of a health of an electrical asset;
analyze a direction to a fault; or
synchronize monitoring nodes.

8. The system of claim 1, wherein, the central computing system comprises processing circuitry configured to, based on the data from the at least one secondary node:
estimate a powerline-operability state;
identify faulted segment of the powerline;
determine a fault response;
determine a precise fault location along the powerline;
measure a synchrophasor;
reduce conservation-voltage;
control voltage;
perform predictive maintenance on the powerline;
assess asset risks;
perform load profiling;
classify and learn waveform anomalies;
predict asset failures;
analyze network connectivity;
perform metering;
reconfigure feeder lines; or
generate safety alerts.

9. The system of claim 1, further comprising at least one removable connector device configured to removably and electrically couple the at least one secondary node to the at least one electrical cable.

10. The system of claim 9, wherein the connector device comprises a T-shaped connector device.

11. The system of claim 9, wherein the secondary node comprises an intermediary plug configured to removably couple the at least one secondary node to the connector device.

12. The system of claim 11, wherein the intermediary plug comprises processing circuitry of the secondary node.

13. The system of claim 11, wherein the intermediary plug comprises a test point configured to enable local voltage testing to determine whether the electrical cable is energized while the intermediary plug is engaged with the connector device and while the connector device is engaged with the electrical cable.

14. The system of claim 13, wherein the secondary node further comprises an end cap configured to encapsulate the test point, wherein external connections of the at least one secondary node are routed through the end cap.

15. The system of claim 14, wherein the end cap further comprises processing circuitry of the at least one secondary node.

16. The system of claim 14, wherein primary electronics of the at least one secondary node are housed within a module that is physically distinct from the intermediary plug and from the end cap.

17. The system of claim 9, wherein the at least one secondary node comprises:
an intermediary plug comprising primary electrical coupling for the at least one secondary node;
an extension module comprising processing circuitry of the at least one secondary node; and
an end cap comprising external connections for the at least one secondary node.

18. The system of claim 9, wherein the removable connector device comprises an elbow connector.

19. The system of claim 1, further comprising a plurality of secondary nodes comprising the at least one secondary node, wherein each of the plurality of secondary nodes is coupled to a different respective phase of the one or more electrical cables.

20. The system of claim 19, wherein the at least one secondary node does not have a direct data connection to any other secondary nodes of the plurality of secondary nodes.

21. The system of claim 19, wherein the plurality of secondary nodes comprises two or more secondary nodes each coupled to a different phase of an electrical cable of the electric powerline, wherein the two or more secondary nodes are coupled to each other via a direct data connection.

22. The system of claim 19, wherein the plurality of secondary nodes comprises two or more secondary nodes each coupled to a different phase of an electrical cable of the electric powerline, wherein the at least one secondary node comprises a common set of primary electronics for the two or more secondary nodes, and wherein the at least one secondary node comprises a direct data connection to each of the two or more secondary nodes.

23. The system of claim 19, wherein the plurality of secondary nodes comprises two or more secondary nodes each coupled to a different phase of an electrical cable of the electric powerline, wherein the system further comprises a common electronics module for the two or more secondary nodes of the plurality, wherein the common electronics module is physically distinct from, and communicatively coupled to, the two or more secondary nodes.

24. The system of claim 1, wherein the at least one primary node comprises:
a transceiver including active electronics, an antenna, and Global Positioning System (GPS) circuitry, the transceiver including a housing, the housing mountable to an enclosure, wherein the transceiver is configured to communicate with the central computing system located outside of the enclosure;
a monitoring device disposed in the enclosure that provides data related to a real-time condition of the electric powerline within the enclosure; and
a sensor analytics unit to process the data from the monitoring device, to generate a processed data signal, and to communicate the processed data signal to the transceiver.

25. A secondary monitoring node of a system configured to monitor one or more conditions of an electric powerline comprising one or more electrical cables, wherein the secondary node is operatively coupled to at least one electrical cable of the one or more electrical cables and configured to communicate data via powerline communication to a primary monitoring node of the system, and wherein the primary node is configured to deliver the data to the central computing system.

26.-42. (canceled)

43. A method comprising:
injecting, by a secondary monitoring node of a system configured to monitor one or more conditions of an electric powerline comprising one or more electrical cables, monitoring data into an electrical cable of the one or more electrical cables to which the secondary monitoring node is operatively coupled;
extracting, by a primary monitoring node of the system, the monitoring data from the electrical cable to which the primary monitoring node is operatively coupled; and
transmitting, by the primary monitoring node, the monitoring data to a central computing device of the system.
